(19) United States
(12) Patent Application Publication
(10) Pub. No.: US 2025/0377391 A1
(43) Pub. Date: Dec. 11, 2025

(54) SYSTEM AND METHOD FOR IDENTIFYING A TYPE OF AN ELECTRICAL DEVICE THAT IS PLUGGED INTO A SMART SOCKET

(71) Applicant: Honeywell International Inc., Charlotte, NC (US)

(72) Inventors: Bhupinder Heer, Harrow (GB); Chris Inkpen, Horsham (GB); Philip Anthony Barnett, Essex (GB); Rory Stewart Foxley, Horsham (GB); Shyam Kumar Mohan Das, Rugby (GB); Daniel Egan, Reading (GB); Yuxin Guo, Guildford (GB); Daniela Filcheva, Horsham (GB)

(21) Appl. No.: 18/738,999

(22) Filed: Jun. 10, 2024

(51) Int. Cl. G01R 19/25; G05B 13/02; H02J 13/00; H04L 12/28

(52) U.S. Cl. CPC G01R 19/2513; G05B 13/028; H04L 12/2832; H02J 13/0005; H04L 2012/2841

(57) ABSTRACT

A measurement unit within a smart socket provides a measure related to the current and/or a measure related to the voltage delivered by the smart socket to the appliance to a trained ML Model. In response, the trained ML Model identifies the appliance type of the appliance that is plugged into the socket receptacle of the smart socket as one of the plurality of predetermined appliance types. Power may be turned on/off to the socket receptacle of the smart socket based at least in part on the identified appliance type and/or identifying anomalous operation of the appliance based at least in part on the identified appliance type.

### TECHNICAL FIELD

The present disclosure relates generally to smart sockets. More particularly, the present disclosure relates to identifying a type of an electrical device that is plugged into a smart socket.

### BACKGROUND

Smart sockets are increasingly being used to power a variety of different electrical devices, including appliances. What would be desirable are systems and methods for identifying a particular electrical device type that is currently plugged into a smart socket based at least in part on electrical characteristics of energy delivered by the smart socket to the particular electrical device over time.

### SUMMARY

The present disclosure relates generally to smart sockets, and more particularly to identifying a type of electrical device that is plugged into a smart socket. An illustrative smart socket includes a measurement unit that is configured to sample a current and a voltage delivered by the smart socket to an appliance that is plugged into the smart socket. A trained Machine Learning (ML) Model is stored. The trained ML model is trained to identify an appliance type of the appliance that is plugged into a socket receptacle of the smart socket as one of a plurality of predetermined appliance types based at least in part on a measure related to the current and/or a measure related to the voltage that is delivered by the smart socket to the appliance. The measure related to the current and/or the measure related to the voltage delivered by the smart socket to the appliance is provided to the trained ML Model, and in response, the trained ML model identifies the appliance type of the appliance that is plugged into the socket receptacle of the smart socket as one of the plurality of predetermined appliance types. Power may be turned on/off to the socket receptacle of the smart socket based at least in part on the identified appliance type and/or identifying anomalous operation of the appliance based at least in part on the identified appliance type.

Another example may be found in a system. The illustrative system includes a smart socket and a gateway device that is operatively coupled to the smart socket. The smart socket includes a measurement unit that is configured to sample a current and a voltage delivered by the smart socket to an appliance plugged into a socket receptacle of the smart socket. The gateway device includes a receiver for receiving from the smart socket a measure related to the current and/or a measure related to the voltage delivered by the smart socket to the appliance, and a memory for storing a trained Machine Learning (ML) Model that is trained to identify an appliance type of the appliance that is plugged into the socket receptacle of the smart socket as one of a plurality of predetermined appliance types based at least in part on the measure related to the current and/or the measure related to the voltage delivered by the smart socket to the appliance. The gateway device includes a controller that is operatively coupled to the receiver and the memory. The controller of the gateway device is configured to provide the measure related to the current and/or the measure related to the voltage received from the smart socket to the trained ML Model, and in response, the trained ML model is configured to identify the appliance type of the appliance that is plugged into the socket receptacle of the smart socket as one of the plurality of predetermined appliance types. The controller of the gateway device may be configured to turn power on/off to the socket receptacle of the smart socket based at least in part on the identified appliance type and/or identifying anomalous operation of the appliance based at least in part on the identified appliance type.

Another example may be found in a non-transitory computer readable medium storing instructions that when executed by one or more processors causes the one or more processors to receive a measure related to a current and/or a measure related to a voltage delivered by a smart socket to an appliance. The one or more processors are caused to provide the measure related to the current and/or the measure related to the voltage received from the smart socket to a trained ML Model, and in response, the trained ML model is configured to identify an appliance type of the appliance that is plugged into the smart socket as one of a plurality of predetermined appliance types. The one or more processors are caused to transmit one or more commands to the smart socket to turn power on/off to the appliance based at least in part on the identified appliance type.

The preceding summary is provided to facilitate an understanding of some of the innovative features unique to the present disclosure and is not intended to be a full description. A full appreciation of the disclosure can be gained by taking the entire specification, claims, figures, and abstract as a whole.

### BRIEF DESCRIPTION OF THE FIGURES

The disclosure may be more completely understood in consideration of the following description of various examples in connection with the accompanying drawings, in which:

FIG. 1 is a schematic block diagram showing an illustrative system;

FIG. 2 is a schematic block diagram showing an illustrative system;

FIGS. 3A and 3B are flow diagrams that together show an illustrative method for identifying a type of appliance; and

FIG. 4 is a flow diagram showing an illustrative series of steps that may be carried out by one or more processors when the one or more processors execute instructions stored on a non-transitory computer readable medium.

While the disclosure is amenable to various modifications and alternative forms, specifics thereof have been shown by way of example in the drawings and will be described in detail. It should be understood, however, that the intention is not to limit the disclosure to the particular examples described. On the contrary, the intention is to cover all modifications, equivalents, and alternatives falling within the spirit and scope of the disclosure.

### DESCRIPTION

The following description should be read with reference to the drawings, in which like elements in different drawings are numbered in like fashion. The drawings, which are not necessarily to scale, depict examples that are not intended to limit the scope of the disclosure. Although examples are illustrated for the various elements, those skilled in the art will recognize that many of the examples provided have suitable alternatives that may be utilized.

All numbers are herein assumed to be modified by the term “about”, unless the content clearly dictates otherwise. The recitation of numerical ranges by endpoints includes all numbers subsumed within that range (e.g., 1 to 5 includes 1, 1.5, 2, 2.75, 3, 3.80, 4, and 5).

As used in this specification and the appended claims, the singular forms “a”, “an”, and “the” include the plural referents unless the content clearly dictates otherwise. As used in this specification and the appended claims, the term “or” is generally employed in its sense including “and/or” unless the content clearly dictates otherwise.

It is noted that references in the specification to “an embodiment”, “some embodiments”, “other embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is contemplated that the feature, structure, or characteristic may be applied to other embodiments whether or not explicitly described unless clearly stated to the contrary.

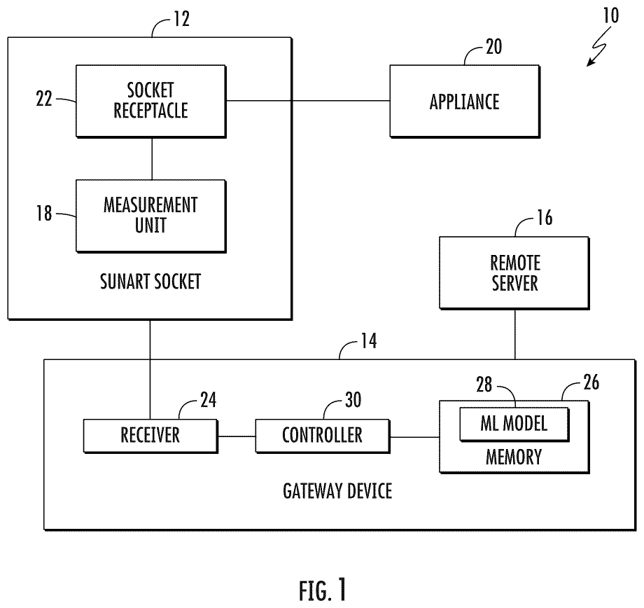

FIG. 1 is a schematic block diagram showing an illustrative system 10. In some cases, the illustrative system 10 may be considered as being part of power system that provides power to one or more electrical devices (e.g. appliances) while also monitoring the performance of the power system, i.e., monitoring the power that is provided to each of the one or more electrical devices. The illustrative system 10 includes a smart socket 12 and a gateway device 14 that is operatively coupled to the smart socket 12. While only a single smart socket 12 is shown, it will be appreciated that the system 10 may include any number of smart sockets 12 operatively coupled to the gateway device 14. In some cases, the system 10 may include a large number of smart sockets 12 that are each operatively coupled to the gateway device 14. In some cases, the gateway device 14 may itself be operatively coupled with a remote server 16, but this is not required in all cases.

The smart socket 12 (or each smart socket 12, if there are more than one) includes a measurement unit 18 that is configured to sample over time a current and a voltage that is being delivered by the smart socket 12 to an appliance 20 that is plugged into a socket receptacle 22 of the smart socket 12. In some cases, the measurement unit 18 of the smart socket 12 may be configured to sample a temperature inside of the smart socket 12. In some cases, the measurement unit 18 of the smart socket 12 may be configured to sample a measure related to a power and/or energy delivered by the smart socket 12 to the appliance 20. In some cases, the measure related to the current and/or the measure related to the voltage delivered by the smart socket 12 to the appliance 20 may correspond to or be used to determine a power factor that is delivered by the smart socket 12 to the appliance 20. In some cases, the measurement unit 18 may be configured to sample the current and the voltage delivered by the smart socket to the appliance at a sample rate of one sample per two seconds, one sample per one second, one sample per 100 ms, one sample per 10 ms, one sample per 1 ms, or any other suitable sample rate.

While a single socket receptacle 22 is shown, in some cases the smart socket 12 may include two or more socket receptacles 22. The socket receptacle 22 may include a hot female terminal and a neutral female terminal (neither are explicitly shown) that accommodate a hot male conductor and a neutral female terminal, respectively, of an electrical plug (not explicitly shown) that is operatively coupled with the appliance 20. In some cases, the socket receptacle 22 also includes a ground female terminal that accommodates a corresponding male ground conductor of the electrical plug.

In the example shown, the gateway device 14 includes a receiver 24 for receiving from the smart socket 12 a measure related to the current and/or a measure related to the voltage delivered by the smart socket 12 to the appliance 20. The gateway device 14 includes a memory 26 for storing a trained Machine Learning (ML) Model 28 that is trained to identify an appliance type of the appliance 20 that is plugged into the socket receptacle 22 of the smart socket 12 as one of a plurality of predetermined appliance types based at least in part on the measure related to the current and/or the measure related to the voltage delivered by the smart socket 12 to the appliance 20. In some cases, the trained ML Model 28 may be a quantized dense neural network model with integer-based weights, which allows for the conversion of traditional floating-point weight representations to integer representations. This enables integer arithmetic to be used when running the trained ML Model 28, significantly enhancing the computational efficiency and energy utilization during operation. In some cases, the trained ML Model 28 may be a Long Short-Term Memory (LSTM) neural network. In some cases, the trained Machine Learning (ML) Model 28 may be a trained regional Machine Learning (ML) Model that is trained for a predetermined geographic region (e.g. Colder Climate versus Warmer Climate).

A controller 30 is operatively coupled to the receiver 24 and the memory 26 and is configured to provide the measure related to the current and/or the measure related to the voltage (e.g. measure related to power) received from the smart socket 12 to the trained ML Model 28, and in response, the trained ML model 28 is configured to identify the appliance type of the appliance 20 that is plugged into the socket receptacle 22 of the smart socket 12 as one of the plurality of predetermined appliance types (e.g. a refrigerator, a microwave, a kettle, a vending machine, a coffee machine, a lamp, a fan, a portable heater, a portable humidifier, a television, a computer monitor, and a computer). In some cases, the controller 30 is configured to turn power on/off to the socket receptacle 22 of the smart socket 12 based at least in part on the identified appliance type and/or when anomalous operation of the appliance 20 is identified based at least in part on the identified appliance type. For example, the controller may send a control signal to turn off power to all lights connected to smart sockets 12 of a facility after normal business hours. In another example, when the ML model identifies an appliance type of an appliance connected to a smart socket, and then the system identifies that the measure related to the current and/or the measure related to the voltage (e.g. measure related to power) provided to the appliance changes indicating anomalous operation of the appliance, the controller may send a control signal to turn off power to the appliance.

In some cases, the system 10 may also include a remote server 16 that is operatively coupled to the gateway device 14. In some cases, the trained ML Model 28 may be trained on the remote server 16 and then downloaded to the memory 26 of the gateway device 14. In some instances, the trained ML Model 28 may be trained on the gateway device 14 and/or on the remote server 16, and then the trained ML Model 28 may be downloaded and stored on the smart socket 12. In some cases, the trained ML Model 28 may be distributed across two or more of the devices, with parts run on two or more of the smart socket 12, the gateway device 14 and/or the remote server 16.

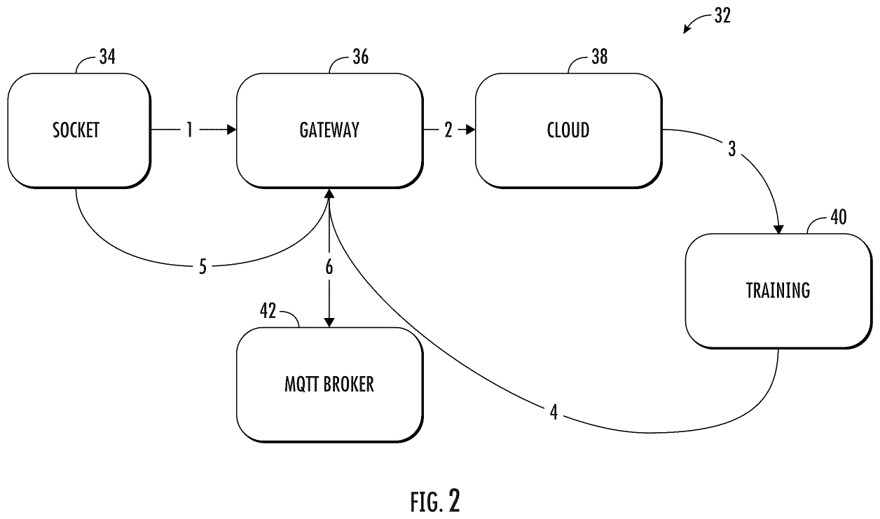

FIG. 2 is a schematic block diagram showing an illustrative system 32. The illustrative system 32 may be considered as being an example of the system 10. The system 32 includes a connected power socket 34 that samples power consumption, power factor, temperature, voltage, current and/or other sensed data at a frequency of 50 or 60 Hz. In the example show, this data is pushed to a local gateway 36 on the network using mesh protocols, as shown at 1. Data from the gateway 36 is aggregated and is sent to the cloud 38 using MQTT (Message Queuing Telemetry Transport), as indicated at 2. Data from the cloud 38 is forwarded to a Training AIML system 40, as indicated at 3. Inferences on predicting the equipment connected to the socket are carried out within the Training AIML system 40. A training model or updated training model is generated within the Training AIML system 40 and is delivered to the gateway 36, as indicated at 4. The gateway 36 is able to deploy local inferences on the data 1 that is pushed to the local gateway 36 from the socket 34, as indicated at 5. In some cases, the gateway 36 delivers local inferences (e.g. determined appliance type) to a local MQTT broker 42 for consumption by further devices/systems, as indicated at 6.

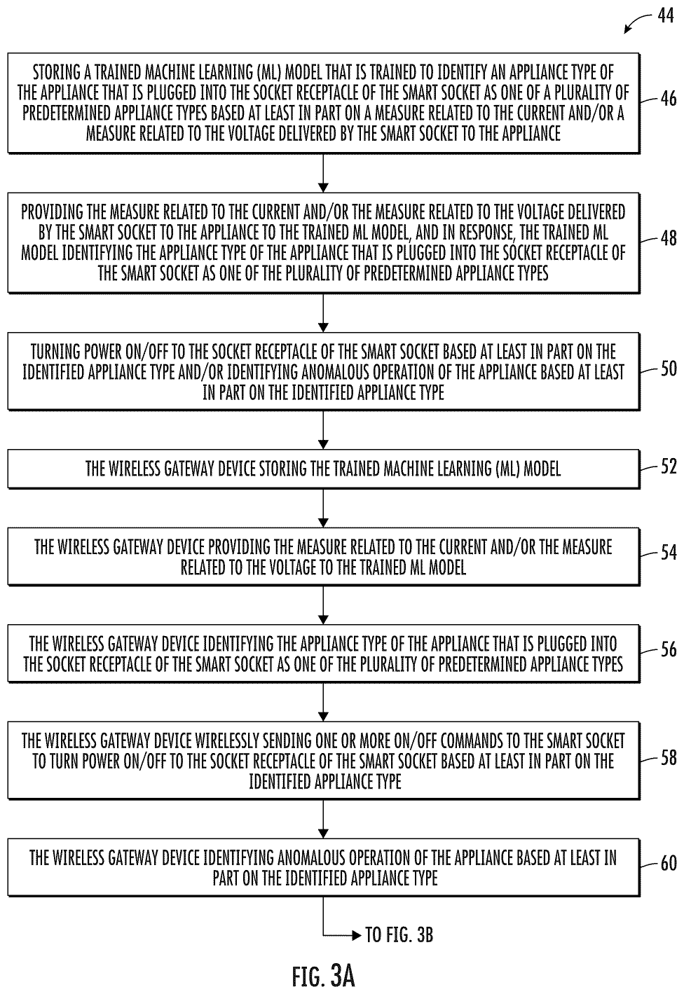

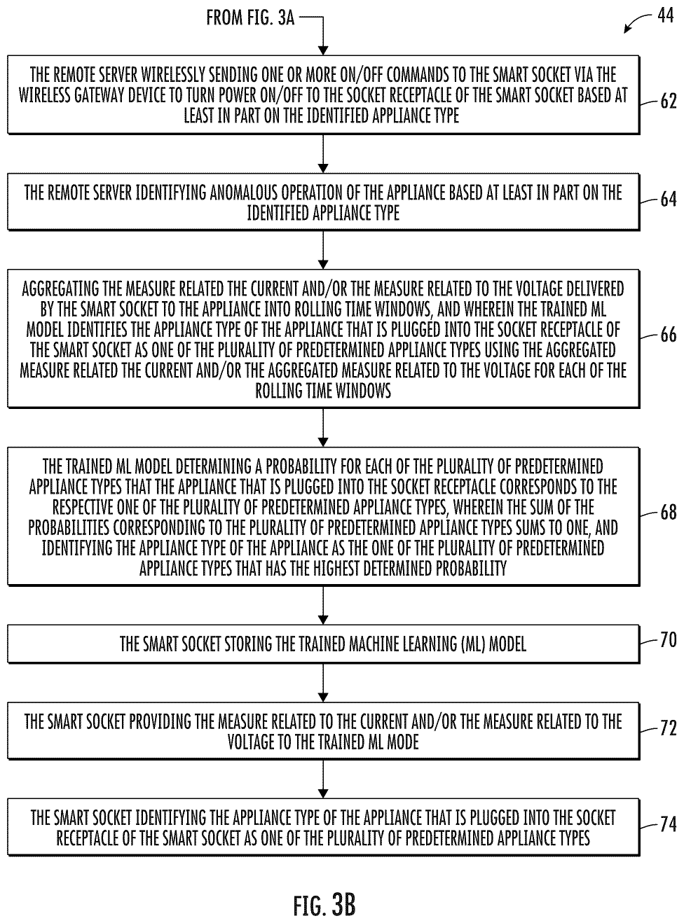

FIGS. 3A and 3B are flow diagrams that together show an illustrative method 44 for identifying a type of an appliance (such as the appliance 20) that is plugged into a socket receptacle (such as the socket receptacle 22) of a smart socket (such as the smart socket 12), wherein the smart socket includes a measurement unit (such as the measurement unit 18) that is configured to sample a current and a voltage delivered by the smart socket to the appliance. The method 44 includes storing a trained Machine Learning (ML) Model (such as the trained ML Model 28) that is trained to identify an appliance type of the appliance that is plugged into the socket receptacle of the smart socket as one of a plurality of predetermined appliance types based at least in part on a measure related to the current and/or a measure related to the voltage delivered by the smart socket to the appliance, as indicated at block 46. As an example, the plurality of predetermined appliance types may include two or more of a refrigerator, a microwave, a kettle, a vending machine, a coffee machine, a lamp, a fan, a portable heater, a portable humidifier, a television, a computer monitor, and a computer. The measure related to the current and/or the measure related to the voltage delivered by the smart socket to the appliance is provided to the trained ML Model, and in response, the trained ML model identifies the appliance type of the appliance that is plugged into the socket receptacle of the smart socket as one of the plurality of predetermined appliance types, as indicated at block 48. In some cases, the power to the socket receptacle of the smart socket may be turned on/off based at least in part on the identified appliance type and/or when anomalous operation of the appliance is identified based at least in part on the identified appliance type, as indicated at block 50.

In some cases, the smart socket may be wirelessly coupled to a wireless gateway device (such as the gateway device 14), and wherein the smart socket may be configured to wirelessly transmit the measure related to the current and/or the measure related to the voltage to the wireless gateway device. The method 44 may further include the wireless gateway device storing the trained Machine Learning (ML) Model, as indicated at block 52. The method 44 may further include the wireless gateway device providing the measure related to the current and/or the measure related to the voltage to the trained ML Model, as indicated at block 54. The method 44 may further include the wireless gateway device identifying the appliance type of the appliance that is plugged into the socket receptacle of the smart socket as one of the plurality of predetermined appliance types, as indicated at block 56. In some cases, the method 44 may further include the wireless gateway device wirelessly sending one or more on/off commands to the smart socket to turn power on/off to the socket receptacle of the smart socket based at least in part on the identified appliance type, as indicated at block 58. The method 44 may further include the wireless gateway device identifying anomalous operation of the appliance based at least in part on the identified appliance type and subsequent measures related to the current and/or the measure related to the voltage drawn by the identified appliance, as indicated at block 60.

In some cases, the wireless gateway device may be operatively coupled to a remote server (such as the remote server 16). Continuing on FIG. 3B, the illustrative method 44 may include the remote server wirelessly sending one or more on/off commands to the smart socket via the wireless gateway device to turn power on/off to the socket receptacle of the smart socket based at least in part on the identified appliance type, as indicated at block 62. In some cases, the method 44 may include the remote server identifying anomalous operation of the appliance based at least in part on the identified appliance type and subsequent measures related to the current and/or the measure related to the voltage drawn by the identified appliance, as indicated at block 64.

In some cases, the measurement unit of the smart socket may be configured to sample a temperature inside of the smart socket, and the trained Machine Learning (ML) Model may be trained to identify the appliance type based at least in part on the measure related to the current delivered by the smart socket to the appliance, the measure related to the voltage delivered by the smart socket to the appliance and the temperature inside of the smart socket. In some cases, the measurement unit of the smart socket may be configured to sample a measure related to a power factor delivered by the smart socket to the appliance, and the trained Machine Learning (ML) Model may be trained to identify the appliance type based at least in part on the measure related to the power factor delivered by the smart socket to the appliance. The measure related to the current and/or the measure related to the voltage delivered by the smart socket to the appliance may be used to identify a power factor delivered by the smart socket to the appliance. In some cases, the current and the voltage delivered by the smart socket to the appliance may be sampled at a sample rate of one sample per two seconds, one sample per one second, one sample per 100 ms, one sample per 10 ms, one sample per 1 ms, or any other suitable sample rate.

In some cases, the method 44 may further include dividing and/or aggregating the measures related the current and/or the measures related to the voltage delivered by the smart socket to the appliance into rolling time windows, and wherein the trained ML model may identify the appliance type of the appliance that is plugged into the socket receptacle of the smart socket as one of the plurality of predetermined appliance types using the measures related the current and/or the measure related to the voltage occurring during each of the rolling time windows, as indicated at block 66. For example, the metrics may be collected into 5-minute rolling windows, wherein a past 5 minute window of metrics gets sent to the trained ML model, and the windows shifts every minute. This is just an example.

In some cases, the trained Machine Learning (ML) Model is a trained regional Machine Learning (ML) Model that is trained for a predetermined geographic region (e.g. Colder Climate, Warmer Climate, different countries, etc.). In some cases, the method 44 may further include the trained ML model determining a probability for each of the plurality of predetermined appliance types that the appliance that is plugged into the socket receptacle corresponds to the respective one of the plurality of predetermined appliance types, wherein the sum of the probabilities corresponding to the plurality of predetermined appliance types sums to one, and identifying the appliance type of the appliance as the one of the plurality of predetermined appliance types that has the highest determined probability, as indicated at block 68.

In some cases, the method 44 may further include the smart socket storing the trained Machine Learning (ML) Model, as indicated at block 70. The method 44 may further include the smart socket providing the measure related to the current and/or the measure related to the voltage to the trained ML Model, as indicated at block 72. The method 44 may further include the smart socket identifying the appliance type of the appliance that is plugged into the socket receptacle of the smart socket as one of the plurality of predetermined appliance types, as indicated at block 74. In some cases, the trained ML model may include a quantized dense neural network model with integer-based weights, which allows for the conversion of traditional floating-point weight representations to integer representations. This enables integer arithmetic to be used when running the trained ML Model, significantly enhancing the computational efficiency and energy utilization during operation. In some cases, the trained ML Model may include a Long Short-Term Memory (LSTM) neural network.

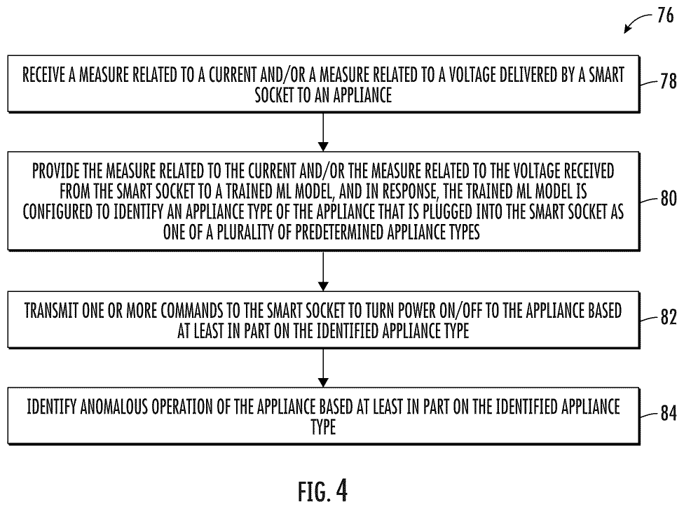

FIG. 4 is a flow diagram showing an illustrative series of steps 76 that may be carried out by one or more processors that are executing instructions that are stored on a non-transitory computer readable medium. As an example, the one or more processors may be part of the controller 30 within the gateway device 14. In another example, the one or more processors may be disposed within the smart socket 12. The one or more processors are caused to receive a measure related to a current and/or a measure related to a voltage delivered by a smart socket to an appliance, as indicated at block 78. The one or more processors are caused to provide the measure related to the current and/or the measure related to the voltage received from the smart socket to a trained ML Model, and in response, the trained ML model is configured to identify an appliance type of the appliance that is plugged into the smart socket as one of a plurality of predetermined appliance types, as indicated at block 80. In some cases, the one or more processors are caused to transmit one or more commands to the smart socket to turn power on/off to the appliance based at least in part on the identified appliance type, as indicated at block 82. In some cases, the one or more processors may be caused to identify anomalous operation of the appliance based at least in part on the identified appliance type, as indicated at block 84.

Having thus described several illustrative embodiments of the present disclosure, those of skill in the art will readily appreciate that yet other embodiments may be made and used within the scope of the claims hereto attached. It will be understood, however, that this disclosure is, in many respects, only illustrative. Changes may be made in details, particularly in matters of shape, size, arrangement of parts, and exclusion and order of steps, without exceeding the scope of the disclosure. The disclosure's scope is, of course, defined in the language in which the appended claims are expressed.

What is claimed is:

1. A method for identifying a type of an appliance that is plugged into a socket receptacle of a smart socket, wherein the smart socket includes a measurement unit that is configured to sample a current and a voltage delivered by the smart socket to the appliance, the method comprising:
storing a trained Machine Learning (ML) Model that is trained to identify an appliance type of the appliance that is plugged into the socket receptacle of the smart socket as one of a plurality of predetermined appliance types based at least in part on a measure related to the current and/or a measure related to the voltage delivered by the smart socket to the appliance;
providing the measure related to the current and/or the measure related to the voltage delivered by the smart socket to the appliance to the trained ML Model, and in response, the trained ML model identifying the appliance type of the appliance that is plugged into the socket receptacle of the smart socket as one of the plurality of predetermined appliance types; and
turning power on/off to the socket receptacle of the smart socket based at least in part on the identified appliance type and/or identifying anomalous operation of the appliance based at least in part on the identified appliance type.

2. The method of claim 1, wherein the smart socket is wirelessly coupled to a wireless gateway device, and wherein the smart socket is configured to wirelessly transmit the measure related to the current and/or the measure related to the voltage to the wireless gateway device, and wherein the method further comprises the wireless gateway device:
storing the trained Machine Learning (ML) Model;
providing the measure related to the current and/or the measure related to the voltage to the trained ML Model; and
identifying the appliance type of the appliance that is plugged into the socket receptacle of the smart socket as one of the plurality of predetermined appliance types.

3. The method of claim 2, wherein the method further comprises the wireless gateway device:
wirelessly sending one or more on/off commands to the smart socket to turn power on/off to the socket receptacle of the smart socket based at least in part on the identified appliance type; and/or
identifying anomalous operation of the appliance based at least in part on the identified appliance type.

4. The method of claim 2, wherein the wireless gateway device is operatively coupled to a remote server, and wherein the method further comprises the remote server:
wirelessly sending one or more on/off commands to the smart socket via the wireless gateway device to turn power on/off to the socket receptacle of the smart socket based at least in part on the identified appliance type; and/or
identifying anomalous operation of the appliance based at least in part on the identified appliance type.

5. The method of claim 1, wherein the plurality of predetermined appliance types includes two or more of a refrigerator, a microwave, a kettle, a vending machine, a coffee machine, a lamp, a fan, a portable heater, a portable humidifier, a television, a computer monitor, and a computer.

6. The method of claim 1, wherein the measurement unit of the smart socket is configured to sample a temperature inside of the smart socket, and the trained Machine Learning (ML) Model is trained to identify the appliance type based at least in part on the measure related to the current delivered by the smart socket to the appliance, the measure related to the voltage delivered by the smart socket to the appliance and the temperature inside of the smart socket.

7. The method of claim 1, wherein the measurement unit of the smart socket is configured to sample a measure related to a power factor delivered by the smart socket to the appliance, and wherein the trained Machine Learning (ML) Model is trained to identify the appliance type based at least in part on the measure related to the power factor delivered by the smart socket to the appliance.

8. The method of claim 1, wherein the measure related to the current and/or the measure related to the voltage delivered by the smart socket to the appliance corresponds to a power factor delivered by the smart socket to the appliance.

9. The method of claim 1, wherein the measurement unit is configured to sample the current and the voltage delivered by the smart socket to the appliance at a sample rate of at least 1 sample per 2 seconds.

10. The method of claim 9, further comprising aggregating the measure related the current and/or the measure related to the voltage delivered by the smart socket to the appliance into rolling time windows, and wherein the trained ML model identifies the appliance type of the appliance that is plugged into the socket receptacle of the smart socket as one of the plurality of predetermined appliance types using the aggregated measure related the current and/or the aggregated measure related to the voltage for each of the rolling time windows.

11. The method of claim 1, wherein the trained Machine Learning (ML) Model is a trained regional Machine Learning (ML) Model that is trained for a predetermined geographic region.

12. The method of claim 1, wherein the method further comprises the trained ML model determining a probability for each of the plurality of predetermined appliance types that the appliance that is plugged into the socket receptacle corresponds to the respective one of the plurality of predetermined appliance types, wherein the sum of the probabilities corresponding to the plurality of predetermined appliance types sums to one, and identifying the appliance type of the appliance as the one of the plurality of predetermined appliance types that has the highest determined probability.

13. The method of claim 1, wherein the method further comprises the smart socket:
storing the trained Machine Learning (ML) Model;
providing the measure related to the current and/or the measure related to the voltage to the trained ML Model; and
identifying the appliance type of the appliance that is plugged into the socket receptacle of the smart socket as one of the plurality of predetermined appliance types.

14. The method of claim 1, wherein the trained ML model comprises a quantized dense neural network model with integer-based weights.

15. The method of claim 1, wherein the trained ML Model comprises a Long Short-Term Memory (LSTM) neural network.

16. A system comprising:
a smart socket, wherein the smart socket includes a measurement unit that is configured to sample a current and a voltage delivered by the smart socket to an appliance plugged into a socket receptacle of the smart socket;
a gateway device operatively coupled to the smart socket, the gateway device including:
a receiver for receiving from the smart socket a measure related to the current and/or a measure related to the voltage delivered by the smart socket to the appliance;
a memory for storing a trained Machine Learning (ML) Model that is trained to identify an appliance type of the appliance that is plugged into the socket receptacle of the smart socket as one of a plurality of predetermined appliance types based at least in part on the measure related to the current and/or the measure related to the voltage delivered by the smart socket to the appliance;
a controller operatively coupled to the receiver and the memory, the controller configured to:
provide the measure related to the current and/or the measure related to the voltage received from the smart socket to the trained ML Model, and in response, the trained ML model is configured to identify the appliance type of the appliance that is plugged into the socket receptacle of the smart socket as one of the plurality of predetermined appliance types; and
turn power on/off to the socket receptacle of the smart socket based at least in part on the identified appliance type and/or identify anomalous operation of the appliance based at least in part on the identified appliance type.

17. The system of claim 16, wherein the trained ML model comprises one or more of:
a quantized dense neural network model with integer-based weights; and
a Long Short-Term Memory (LSTM) neural network.

18. The system of claim 16, comprising:
a remote server operatively coupled to the gateway device, wherein the trained ML model is trained on the remote server and then downloaded to the memory of the gateway device.

19. A non-transitory computer readable medium storing instructions that when executed by one or more processors causes the one or more processors to:
receive a measure related to a current and/or a measure related to a voltage delivered by a smart socket to an appliance;
provide the measure related to the current and/or the measure related to the voltage received from the smart socket to a trained ML Model, and in response, the trained ML model is configured to identify an appliance type of the appliance that is plugged into the smart socket as one of a plurality of predetermined appliance types; and
transmit one or more commands to the smart socket to turn power on/off to the appliance based at least in part on the identified appliance type.

20. The non-transitory computer readable medium of claim 19, wherein the instructions cause the one or more processors to identify anomalous operation of the appliance based at least in part on the identified appliance type.
